(19) United States
(12) Patent Application Publication
(10) Pub. No.: US 2018/0075814 A1
(43) Pub. Date: Mar. 15, 2018

(54) OLED Display Backlight

(71) Applicant: INTEL CORPORATION, Santa Clara, CA (US)

(72) Inventor: Kunjal Parikh, San Jose, CA (US)

(73) Assignee: INTEL CORPORATION, Santa Clara, CA (US)

(21) Appl. No.: 15/697,057

(22) Filed: Sep. 6, 2017

Related U.S. Application Data
(60) Provisional application No. 62/385,799, filed on Sep. 9, 2016.

(51) Int. Cl. G09G 3/36; G02F 1/1335; H01L 51/52; H01L 27/32

(52) U.S. Cl. CPC G09G 3/3622; G02F 1/133603; G09G 2320/046; H01L 27/3232; G09G 2320/0626; H01L 51/525

(57) ABSTRACT

In one example, a display backlight includes organic light emitting diodes patterned in a segmented manner, and one or more spacers spaced between the white organic light emitting diodes.

### CROSS-REFERENCE TO RELATED APPLICATIONS

This application is related to U.S. Provisional Patent Application Ser. No. 62/385,799, filed on Sep. 9, 2016, titled “OLED Display Backlight”. This application claims priority of U.S. Provisional Patent Application Ser. No. 62/385,799, filed on Sep. 9, 2016, titled “OLED Display Backlight”. U.S. Provisional Patent Application Ser. No. 62/385,799, filed on Sep. 9, 2016, titled “OLED Display Backlight” is incorporated herein by reference.

### TECHNICAL FIELD

This disclosure relates generally to a segmented and/or patterned Organic Light Emitting Diode (OLED) backlight.

### BACKGROUND

A High Dynamic Range (HDR) display is a display that provides supreme content at a very high contrast ratio. HDR display can provide a high level of image quality relative to SDR (Standard Dynamic Range) display. HDR display provides a next level of image quality. HDR display can require high end processing such as high end core processing to drive compute through the display pipeline. HDR displays are typically used in TVs and large footprint monitor implementations, but not in mobile devices.

### BRIEF DESCRIPTION OF THE DRAWINGS

The following detailed description may be better understood by referencing the accompanying drawings, which contain specific examples of numerous features of the disclosed subject matter.

FIG. 1, which includes FIG. 1A, FIG. 1B, and FIG. 1C, illustrates a display backlight;

FIG. 2 illustrates a display backlight;

FIG. 3 illustrates a portion of a display backlight;

FIG. 4 illustrates a manufacturing process of a display;

FIG. 5 illustrates a display;

FIG. 6 illustrates a system;

FIG. 7 illustrates display image sticking avoidance;

FIG. 8 illustrates a computing device;

FIG. 9 illustrates one or more processor and one or more tangible, non-transitory computer readable media;

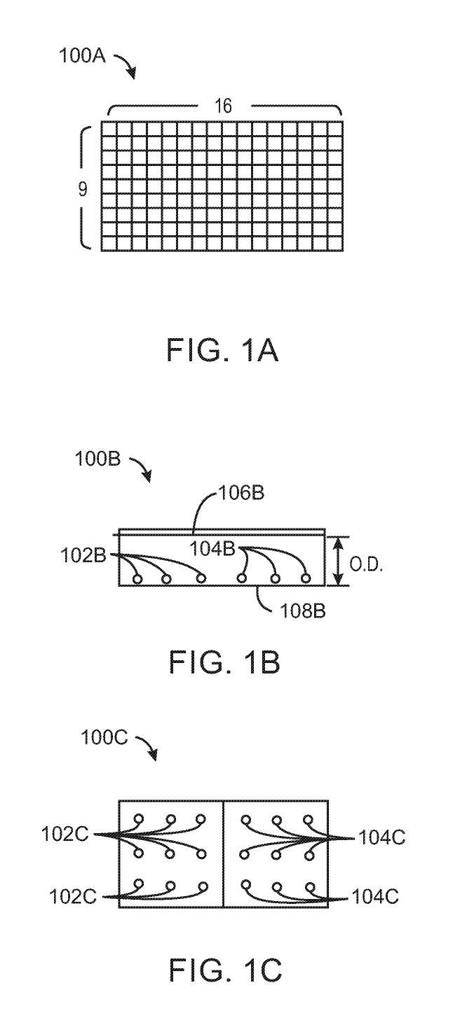

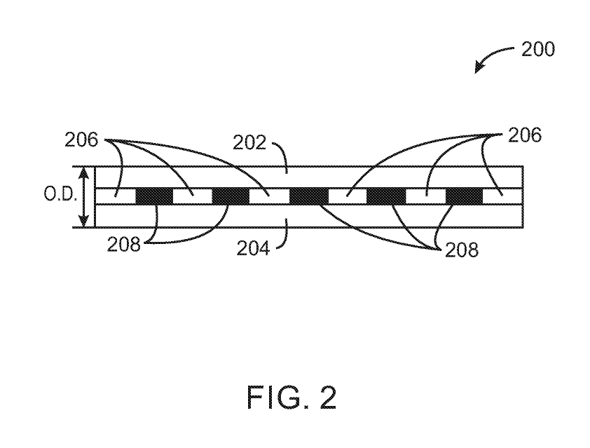

In some cases, the same numbers are used throughout the disclosure and the figures to reference like components and features. In some cases, numbers in the 100 series refer to features originally found in FIG. 1; numbers in the 200 series refer to features originally found in FIG. 2; and so on.

### DESCRIPTION OF THE EMBODIMENTS

Some embodiments relate to a segmented and/or patterned Organic Light Emitting Diode (OLED) backlight.

In some embodiments, white OLED material is used in a segmented fashion (and/or a patterned fashion). In some embodiments, white OLED material is segmented and assembled in a manner to provide high dynamic range (HDR) display content capabilities.

Some embodiments can enable high dynamic range (HDR) display for mobile devices using an OLED backlight with a thin stack (for example, a backlight with a small optical distance).

In some embodiments, OLED pixels are patterned in multiple segments. In some embodiments, patterned and/or segmented white OLEDs are used as a backlight solution. In some embodiments, a patterned and/or white OLED arrangement can be used as a backlight solution to enable an HDR display experience.

Displays typically use a backlight with a display screen arranged over the backlight. For a phone display with 3 million pixels, for example, an ideal backlight would have 3 million LEDs in the backlight at the back side of the display in order to have full control on an individual pixel level. However, this is impractical due to power and cost limitations as well as physical size limitations. Therefore, an LED backlight typically has much fewer LEDs than the display itself (for example, a backlight might have thousands of LEDs while the display screen itself has millions of LEDs). As a result, there is a low-resolution impact based on how the architecture of the backlight and display screen are implemented. Additionally, use of a typical LED, which is a relatively large sized LED (for example, LED structure in a size range of tens of microns) can require a high optical distance (O.D.) so that light can cover a certain distance before it diffuses out. This higher optical distance increases the necessary thickness size of the backlight. When using a smaller number of LEDs for the backlight, the LEDs are widely spaced and a large optical distance (O.D.) is necessary in order to ensure that every light is diffused across the backlight array so that no black spot zones are present. Therefore, this type of technology is not advantageous for smaller form factor devices and/or mobile devices (such as phones, tablets, notebooks, etc.) because it is too thick for small devices, and is limited to larger form factors such as TVs and large monitors.

FIG. 1A illustrates a display backlight 100A with 144 zones arranged in 9 rows and 16 columns. Each of the zones of display backlight 100A can include, for example, 9 direct lit LEDs.

FIG. 1B illustrates a display backlight 100B in a cross section view. For example, backlight 100B may illustrate display backlight 100A of FIG. 1A taken in a cross section view. FIG. 1B illustrates two zones of display backlight 100B, including three illustrated LEDs 102B from a first zone of backlight 100B and three illustrated LEDs 104B from a second zone of backlight 100B. Display backlight 100B also includes a film stacking and diffuser plate 106B near the top of FIG. 1B and a reflector 108B near the bottom of FIG. 1B. FIG. 1B illustrates an optical distance (O.D.) between the film stacking and diffuser plate 106B and the reflector 108B.

FIG. 1C illustrates a display backlight 100C from a top view. For example, backlight 100C may illustrate display backlight 100A of FIG. 1A and/or display backlight 100B of FIG. 1B. FIG. 1C illustrates two zones of display backlight 100C, including nine LEDs 102C from a first zone of backlight 100C and nine LEDs 104C from a second zone of backlight 100C. For example, the nine LEDs 102C can be included in one of the 144 zones illustrated in FIG. 1A and the nine LEDs 104C can be included in another of the 144 zones illustrated in FIG. 1A.

FIG. 1A, FIG. 1B and/or FIG. 1C each show a backlight with a number of zones and a number of LEDs in each zone. It is noted that a different number of zones and/or a different number of LEDs in each zone may be implemented.

Implementations of high dynamic range (HDR) display require a direct lit LED backlight with a high optical distance (O.D.) in order to minimize the number of LED strings (or zones) due to cost constraints, and image quality is not at or near pixel level. For example, in such implementations, the high O.D. may be greater than 10 mm.

In order to create a high image quality at the pixel level, a separate LED backlight could be used for every LED pixel in order to drive true pixel level HDR capabilities. However, this is often not a practical implementation.

For an example of a backlight implementation for a 31.5 inch display monitor, 1296 LEDs can be used as illustrated in FIG. 1A, FIG. 1B, and/or FIG. 1C. In this implementation, 1296 LEDs are used in 9 rows×16 columns×9 LEDs per zone, where each zone is 43.62 mm by 43.62 mm, for example. The optical distance (O.D.) in this implementation may be 14 mm or greater, and the power consumption of the backlight may be around 150 Watts. The O.D. relates directly to thickness of the display monitor, which is not as important for large displays, but becomes much more important as the size of the monitor decreases. For small displays, an O.D. of 14 mm is not feasible. For example, in small compact form factor used in mobile devices such as phablets, phones, tablets, and/or 2-in-1 devices, etc. (or other mobile devices) a backlight O.D. of 14 mm would not result in a competitive or viable display product.

One solution for backlights using LEDs can include a two dimensional (2D) solution of using an array of LEDs as a backlight in order to enable 2D dimming capabilities for high dynamic range (HDR) content. For example, such a solution may include using a direct backlighting lightbar with LEDs dispersed along the lightbar. A challenge of this approach is the trade-off between HDR resolution and the number of LEDs being used, since cost is driven up as more LEDs are included. For example, as illustrated in FIG. 1A, FIG. 1B, and/or FIG. 1C and as described above, for a 31.5″ monitor, 16×9=144 strings (or zones) of LEDs may be used, with each string (or zone) including 9 LEDs, 1296 LEDs may be necessary. A large number of LEDs in such an implementation results in a large power consumed by the display (for example, around 150 Watts in this example). Additionally, a large optical distance is necessary in view of limited spacing coverage (for example, an optical distance of around 14 mm). For monitor and TV applications, such an implementation is acceptable, but is much less advantageous for tight form factors such as mobile devices.

In some embodiments, HDR implementations of backlights 100A, 100B and/or 100C are limited to very low resolution due to high cost and power consumption.

FIG. 2 illustrates a display backlight 200 in a cross section view. In some embodiments, backlight 200 is a passive matrix based low resolution white organic light emitting diode (OLED) backlight. Backlight 200 includes a protection layer 202 (for example, an encapsulation layer such as a thin film encapsulation layer, a glass layer such as a glass seal, etc.) Backlight 200 also includes a substrate layer 204 made of, for example, plastic or glass (for example, in some embodiments made of passive matrix glass). In some embodiments, layer 204 is a passive matrix backplane layer. In some embodiments, layer 204 is passive matrix glass. Backlight 200 also includes OLED pixels 206 (for example, white OLED pixels, low resolution OLED pixels, and/or low resolution white OLED pixels). In some embodiments, pixels 206 are white OLED pixels arranged, for example, from a top view, in rows and columns. Backlight 200 further includes spacing 208 interspersed between the OLED pixels 206 to provide a segmented layer including pixels 206 and spacing 208 to provide patterned and segmented OLED pixels. In some embodiments, pixels 206 and spacing 208 form patterned white OLEDs forming an array of white OLED pixels and a gap in between the pixels. In some embodiments, layer 204 is a sealant with an encapsulation to provide protection for OLED pixels 206. In some embodiments, backlight 200 is a white OLED backlight that may be stacked with a liquid crystal display (LCD) cell to deliver a thinner stack and high fidelity HDR experience. In some embodiments, the optical distance (O.D.) from the top of layer 202 to the bottom of layer 204 is approximately 0.3 mm. In some embodiments, the optical distance (O.D.) from the top of layer 202 to the bottom of layer 204 is in a range from approximately 0.3 mm to approximately 0.4 mm. In some embodiments, OLED pixels 206 are OLED light emitting devices (for example, white OLED devices) that are very thin (for example, with a thickness in the range of a nanometer or nanometers such as a few nanometers). In some embodiments, OLED pixels 206 are patterned in multiple segments. In some embodiments, patterned white OLEDs are used as a backlight solution.

In some embodiments, a segmented OLED backlight such as backlight 200 uses a lambertian profile of white OLED technology in order to drive thin profile designs. For example, a display including a segmented OLED backlight such as backlight 200 can be two times (or more) thinner than a display including a backlight such as that illustrated in and described in reference to FIG. 1A, FIG. 1B, and/or FIG. 1C.

In some embodiments, the high efficiency of white OLED technology can be, for example, 100 lm/W (100 lumens per Watt). This high efficiency can drive a low power backlight solution. For example, in some embodiments using a 13.3″ backlight display (for example with a 16:9 aspect ratio), a targeted backlight power for 350 nits peak luminance is around 3 or 4 Watts, depending on certain constraints such as the forward voltage Vf of the LEDs being used. This power consumption is much lower than that used for other LED implementations (for example, such as 150 Watts).

In one example, white segment OLED backlight needs are around 7000 nits of luminance (with 5% panel transmittance and 350 nits peak luminance). In this example, white OLED backlight requirements include a peak luminance of 7777.78 cd/m2, an average luminance of 7777.78 cd/m2, a DBEF (brightness enhancement film) backlight polarization film of 0.55, a BEF backlight polarization film of 0.42, a required luminance of 3533.75 cd/m2, backlight chromaticity of x=0.28 and y=0.29, intensity of 109.59 Cd, viewing angle 2.60 sr, flux of 284.93 lm, and backlight efficiency of 1.00. In this example, white OLED backlight power factors include a target heat sink temperature of 40.00 degrees C., required total flux of 284.93 lm, white flux at junction temperature Tj of 25 C of 284.93 lm, typical white LED output of 104.001 lm, forward voltage of the LED(s) Vf of 4.0 volts, current of the LED(s) I of 0.35A, and total power of 3.84 Watts. In another example using similar constraints, a forward voltage of the LED(s) Vf is 3.1 volts, and the total power is 2.97 Watts.

In some embodiments, use of a backlight using white OLED technology results in much lower power consumption. In some embodiments, white OLEDs are very reliable at high backlight brightness. In some embodiments, OLED patterning and/or white OLED segmented patterning is much less costly than other LED backlight implementations. In some embodiments, given direct emission of OLED technology, savings result due to backlight injection efficiency, which can be assumed at 100% for OLED, since OLED is a direct emission device (vs. LED efficiency which is around 70% or so).

In some embodiments, direct patterned white OLEDs may be used as a backlight. This may be coupled with LCD stack layers to enable thin displays (for example, for high dynamic range applications). The thin OLED profile of approximately 100 nm vs. the taller LED aspect ratio of approximately 5 μm as well as the lambertian intensity profile of OLED have the ability to drive a thinner stack structure backlight design. For example, the profile may be around 0.3 mm or around 0.4 mm for OLED vs. 10 mm or 14 mm or larger for designs using other LEDs.

In some embodiments, a large area structure OLED is patterned (and/or segmented) using a screen printing mask at much lower cost (vs. fine metal mask technology) and can be driven by a passive matrix backplane. Use of large area structure OLED technology according to some embodiments also can provide a low current drive density of less than 0.1 A/cm2, which preserves the lifetime and reliability of white OLED devices for the lifetime of the products (which can typically be 5,000 to 10,000 hours of operation).

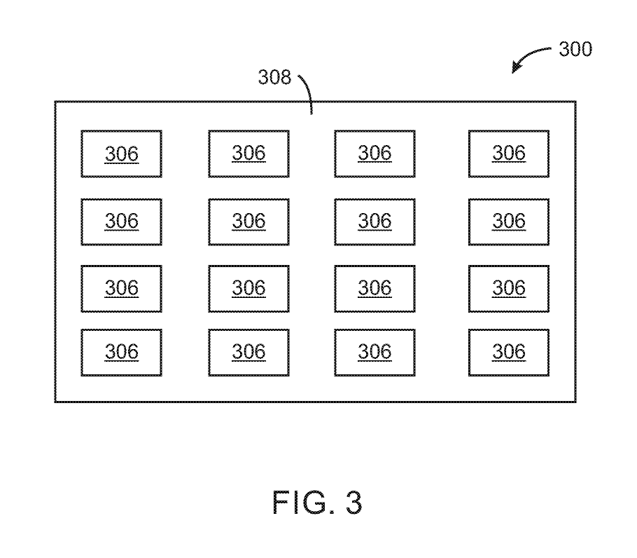

FIG. 3 illustrates a portion 300 of a backlight taken from a top view. For example, in some embodiments, portion 300 illustrates the layer in FIG. 2 including white OLEDs 206 and spacing 208 from a top view. Backlight portion 300 includes white OLEDs 306 and spacing 308. In some embodiments, pixels 306 and spacing 308 form patterned white OLEDs forming an array of white OLED pixels and a gap in between the pixels. Although a 4 by 4 matrix of 16 white OLEDs 306 are illustrated in FIG. 3, a backlight according to some embodiments include any number of white OLEDs (for example, patterned and/or segmented white OLEDs). In some embodiments, OLED pixels 306 are patterned in multiple segments. In some embodiments, patterned white OLEDs are used as a backlight solution.

In some embodiments, for a 13.3″ backlight design for a 4K resolution display (with 330 pixels per inch resolution) a segmented white OLED backlight can be implemented using an array of 384 by 216 (82,944) white OLEDs, which results in delivering a 10% pixel ratio with a 33 pixels per inch (PPI) OLED backlight design. In this embodiment, the pixel size can be 768 μm pitch, and input/output (I/O) provides 600 connection options (384+216). The pixel pitch allows current to spread across a large area, which relaxes current density requirements per OLED pixel to less than 0.1 A/cm². At this low current density, white OLED can drive a high lifetime requirement of products beyond 10,000 hours of operation, as typically needed by mobile devices such as phablets, phones, tablets, and/or 2-in-1 devices, etc.

In some embodiments, for a 13.3″ backlight design for a 4K resolution display (with 330 pixels per inch resolution) a segmented white OLED backlight can be implemented using an array of 192 by 108 (20,736) white OLEDs, which results in delivering a 5% pixel ratio with a 17 pixels per inch (PPI) OLED backlight design. In some embodiments, the pixel size can be 1.5 mm pitch, and input/output (I/O) provides 300 connection options (192+108), with routing pitch of 8 μm+2 μm. A bezel routing area of approximately 1.5 mm is available on each side. The pixel pitch can allow current to spread across a large area, which can relax current density requirements per OLED pixel to less than 0.1 A/cm². At this low current density, white OLED can drive a high lifetime requirement of products beyond 10,000 hours of operation, as typically needed by mobile devices such as phablets, phones, tablets, and/or 2-in-1 devices, etc.

In some embodiments (for example, as illustrated in FIG. 2 and/or FIG. 3) a much better HDR experience can be achieved even with only a 5% or 10% pixel ratio relative to an implementation using a solid state type of LED, for example.

In some embodiments, a very bright backlight may be desired. Therefore, a very high current can be provided to each individual OLED pixel. In some embodiments, white OLEDs can be used to drive 0.1 A per cm². A very high lambertian can be delivered. The OLEDs can be significantly diffused in order to deal with a smaller number of segments. A broader illumination of the OLEDs is possible with a segmented design according to some embodiments. Therefore, a high density of segmentation is not necessary according to some embodiments.

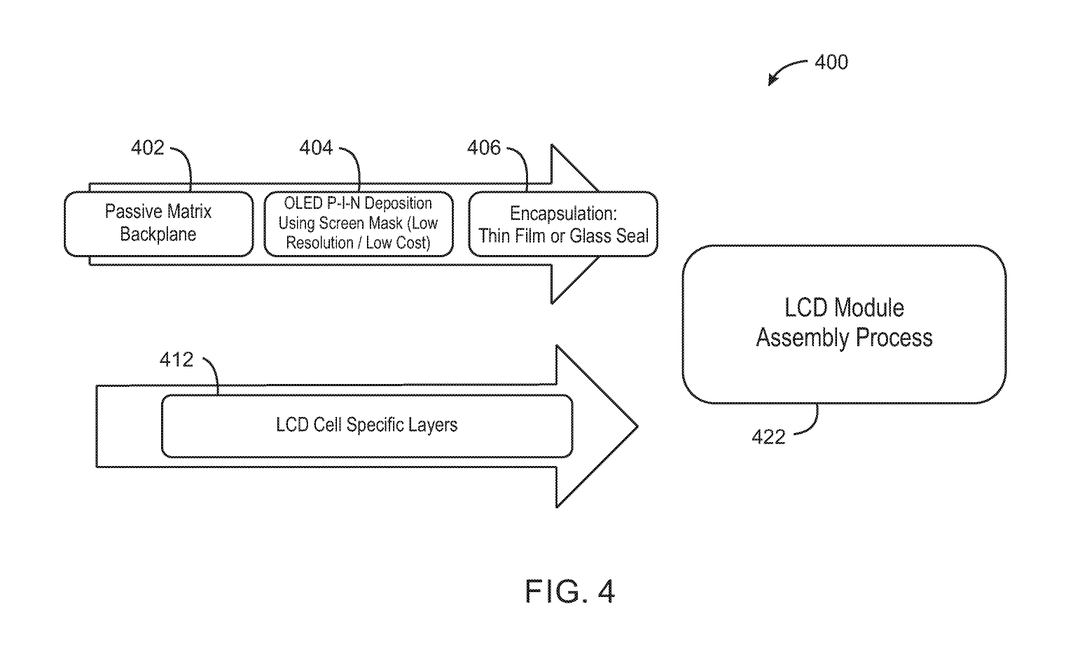

FIG. 4 illustrates a display manufacturing process 400. In some embodiments, process 400 can be implemented in a manner that fits into an existing display process line. In some embodiments, a backlight can be formed at 402, 404 and 406. In some embodiments, the backlight formed at 402, 404, or 406 can be any other backlight herein (for example, backlight 200 of FIG. 2 or backlight 300 of FIG. 3). At 402 a passive matrix backplane can be formed (for example, to form a substrate layer such as layer 204 in FIG. 2). At 404 a screen mask processing can occur. For example, at 404, an OLED layer can be formed (for example, a white OLED layer, a patterned OLED layer, and/or a segmented OLED layer). In some embodiments, 404 can perform OLED P-I-N deposition using, for example, a screen mask. In some embodiments, an expensive screen patterning process is not necessary. A low cost screen mask process may be used at 404 according to some embodiments (for example, a low resolution and/or low cost process may be used). In some embodiments, the OLED layer formation at 404 forms a layer such as the combined OLEDs 206 and spacing 208 in FIG. 2 and/or the layer such as the combined OLEDs 306 and spacing 308 in FIG. 3. At 406 an encapsulation layer can be formed (for example, of thin film and/or a glass seal) on the top of the layer formed at 404. In some embodiments, a layer such as the protection layer 202 of FIG. 2 can be formed at 406.

A display screen such as an LCD display including cell specific layers can be formed at 412 (for example, in parallel with the process at 402, 404 and 406). In some embodiments, the display formed at 412 can be formed at the same time and/or in the same manufacturing process as the backlight formed at 402, 404 and 406. At 422 the formed backlight and display (for example, LCD display) formed at 402, 404, 406 and 412 come together and are integrated using a module assembly of the display screen including the backlight. In some embodiments, 412 can be performed in parallel with 402, 404 and 406 in order to save time and enhance a high throughput and efficiency, which can result in cost savings.

In some embodiments, the manufacturing process 400 of FIG. 4 can use OLED and LCD manufacturing technologies without new infrastructure being required. In some embodiments, a low resolution OLED can be deposited (for example, at 404) using a screen mask process instead of fine metal masks, which can result in cost savings. In some embodiments, a passive matrix backplane can be developed (for example, at 402) using a TFT (thin film transistor) process line, which can result in cost savings. In some embodiments, once a backlight (for example, a backlight manufactured at 402, 404 and 406) and a display cell (manufactured at 412, and/or an LCD display cell) are available, a module and/or assembly process 422 can follow steps for module/assembly (for example, LCD module/assembly steps).

In some embodiments, process 400 of FIG. 4 can use existing infrastructure (for example, existing OLED and/or LCD facilities) to enable segmented OLED driving for an HDR backlight. In some embodiments, flow at 402, 404 and 406 can provide a passive matrix backplane to be patterned through a TFT line. OLED specific deposition (for example, OLED specific P-I-N deposition) can be performed with a low cost screen mask process rather than expensive fine metal mask processing. The top layer can be encapsulated with thin film encapsulation, and/or using a sealant layer to seal the glass. In some embodiments, this can be combined with LCD cell specific layers and follow existing LCD module processes. According to some embodiments, low cost single layer white OLED patterning is implemented using a screen mask process, enabling a much lower cost than an LED type solution.

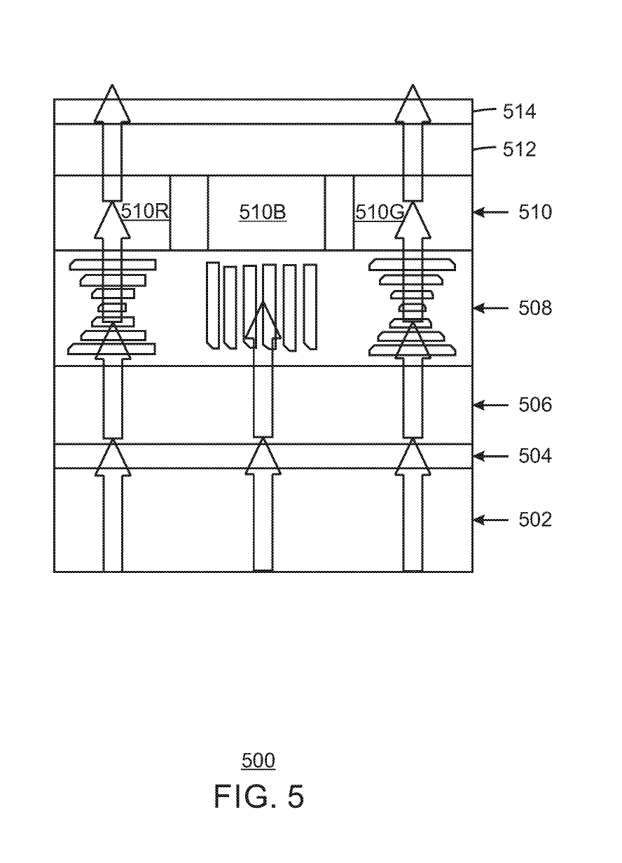

FIG. 5 illustrates a display device 500 (for example, a liquid crystal display or LCD with a backlight 502 or a display screen with a backlight). The display 500 can be any display including portions of any of the elements described herein. For example, display 500 can be a display such as the one formed in reference to FIG. 4. Display 500 includes a backlight 502, polarizer 504, glass 506, liquid crystal 508, color filters 510 (including red filter 510R, blue filter 510B, and green filter 510G), glass 512, and polarizer 514. The display 500 can be a liquid crystal display (LCD). The display can be a flat panel display or other electronically modulated optical device that uses the light-modulating properties of liquid crystals. The backlight 502 can be any backlight discussed herein, such as, for example, backlight 200 of FIG. 2, backlight 300 of FIG. 3, or the backlight formed at 402, 404 and 406 of FIG. 4. The liquid crystals in liquid crystal layer 508 do not emit light directly, but use backlight 502 to produce images.

The arrows pointing from the direction fo the bottom of FIG. 5 to the top of FIG. 5 represent light moving through the display 500. Backlight 502 creates light that moves from the backlight and through the polarizer 504 and the glass 506. Depending on electronic modulation, the crystals 508 can block light or let light pass through layer 508. For example, the crystal below the red filter 510R and the crystal below green filter 510G are illustrated in FIG. 5 as allowing light to pass through to allow red and green light to be shown on the display for the pixel of the display 500 illustrated in FIG. 5. However, the crystal in crystal layer 508 that is below the blue filter 510B is illustrated in FIG. 5 as not allowing light to pass through to blue filter 510B to allow blue light to be shown on the display for the pixel of the display 500 illustrated in FIG. 5.

In some embodiments, backlights illustrated or described herein can be active matrix organic light emitting diode (AMOLED) backlights. OLED backlights such as AMOLED backlights can suffer from image sticking upon prolonged exposure to a static image. In some embodiments, a display image can be monitored (for example, using a video processing unit). In some embodiments, such a video processing unit can be a video processor included within or in conjunction with a display controller, a processor, a central processing unit (CPU), or an SoC (system on chip), for example.

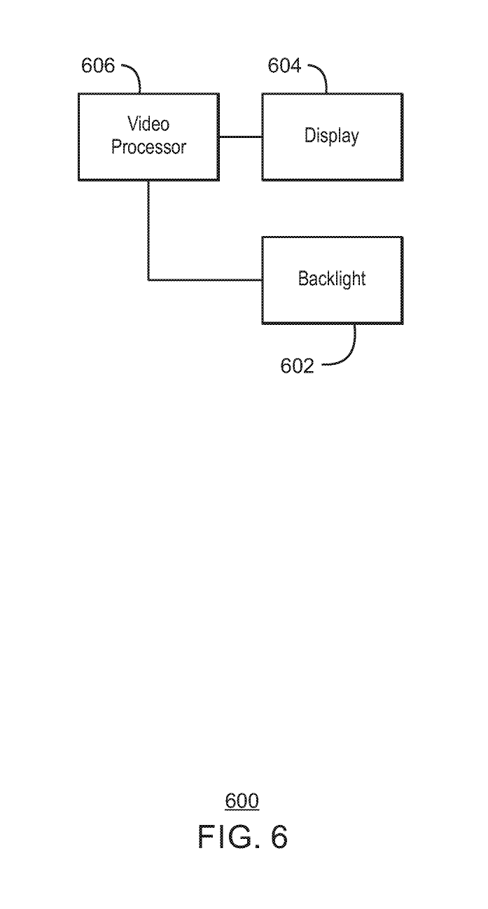

FIG. 6 illustrates a system 600 that includes a backlight 602, a display 604, and a video processor 606. In some embodiments, backlight 602 is an OLED backlight or an AMOLED backlight. In some embodiments, backlight 602 is any backlight described or illustrated herein (for example, such as backlight 200, backlight 300, the backlight formed at 402, 404, and 406, backlight 502, etc). In some embodiments, display 604 can be a display screen. In some embodiments, display 604 can be any display or portion of any display described or illustrated herein (for example, display 602 can include portions of display 500).

As discussed above, OLED backlights such as AMOLED backlights can suffer from image sticking upon prolonged exposure to a static image. In FIG. 6, the video processor can monitor a video frame buffer that buffers an image to be displayed on display 604. In some embodiments, video processor 606 can be included within or can work in association with a display controller, a processor, a central processing unit (CPU), or an SoC (system on chip), for example. In some embodiments, backlight 602, display 604 and video processor 606 can be part of the same display device. In some embodiments, video processor 606 can be in a separate device than a display device including backlight 602 and display 604. Video processor 606 can monitor the display image and provide information relating to whether the display image remains static for a period of time. That information can be provided by the video processor 606 to backlight 602 (for example, to a display driver of backlight 602). In response to the information about whether or not the display image remains static for a period of time, the backlight 602 (or backlight driver within backlight 602) can modulate backlight function as a fully active matrix function during a time frame where there is no static image, and can modulate backlight function to a fully lit backlight condition during a time frame where there is a static image. By fully lighting the backlight, image boundary conditions can be suppressed, and image sticking can be avoided. In some embodiments (for example in some embodiments in which backlight 602 is an AMOLED backlight), a fully lit backlight will not have a negative impact on the image.

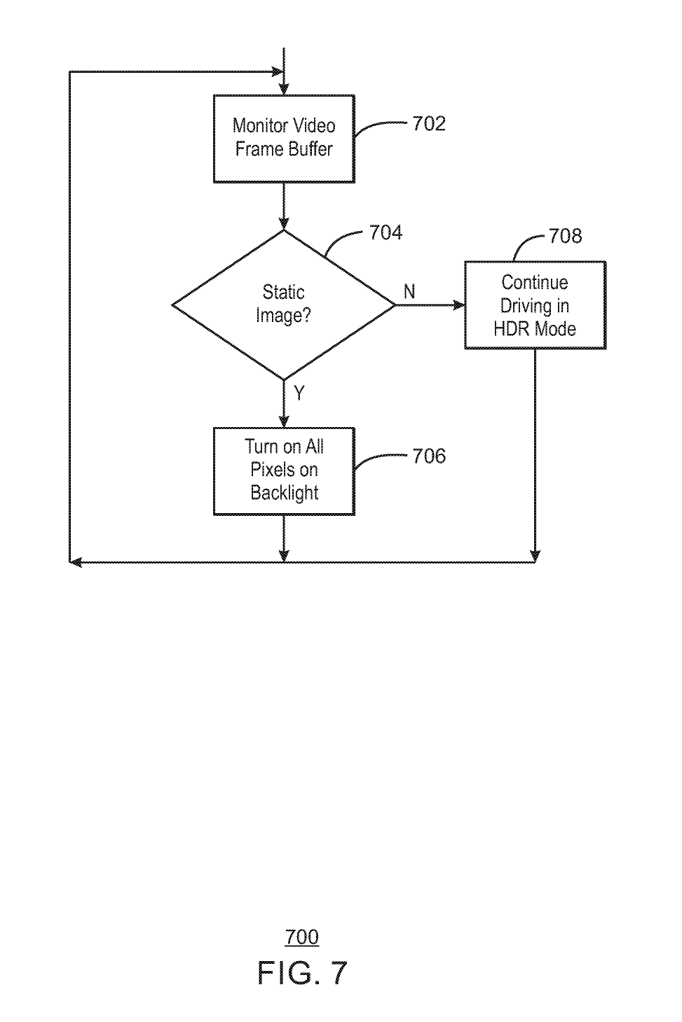

FIG. 7 illustrates a display image sticking avoidance flow 700. In some embodiments, flow 700 can be implemented using a video processor such as, for example, video processor 606. At 702, a display image is monitored (for example, by monitoring a video frame buffer associated with a display image). In some embodiments, the display image monitored at 702 is a display image to be displayed on a display screen. At 704, a decision is made as to whether the display image is a static image. If the display image is a static image at 704 all pixels of a backlight are turned on at 706. For example, the backlight including the pixels that are turned on at 706 can be an OLED backlight or an AMOLED backlight. In some embodiments, this backlight can be any backlight described or illustrated herein. If the display image is not a static image at 704, the backlight (or a backlight driver) continues to drive the backlight (for example, in an HDR mode). In some embodiments, after 706 and/or 708, flow returns to 702 to continue determining whether the display image is static or not, and controlling the backlight in response to that determination.

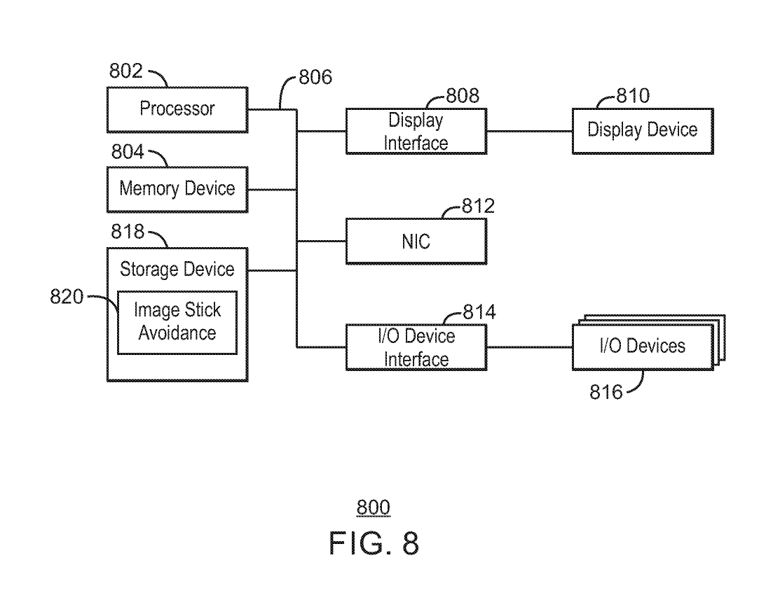

FIG. 8 is a block diagram of an example of a computing device 800. In some embodiments, computing device 800 can include display features including image stick avoidance, for example. The computing device 800 may be, for example, a mobile device, laptop computer, notebook, tablet, all in one, 2 in 1, and/or desktop computer, etc., among others. The computing device 800 may include a processor 802 that is adapted to execute stored instructions, as well as a memory device 804 (and/or storage device 804) that stores instructions that are executable by the processor 802. The processor 802 can be a single core processor, a multi-core processor, a computing cluster, or any number of other configurations. For example, processor 802 can be an Intel® processor such as an Intel® Celeron, Pentium, Core, Core i3, Core i5, or Core i7 processor. In some embodiments, processor 802 can be an Intel® x86 based processor. In some embodiments, processor 802 can be an ARM based processor. The memory device 804 can be a memory device and/or a storage device, and can include volatile storage, non-volatile storage, random access memory, read only memory, flash memory, and/or any other suitable memory and/or storage systems. The instructions that are executed by the processor 802 may also be used to implement display control, backlight control, and/or image stick avoidance as described in this specification.

The processor 802 may also be linked through a system interconnect 806 (e.g., PCI®, PCI-Express®, NuBus, etc.) to a display interface 808 adapted to connect the computing device 800 to a display device 810. The display device 810 may include a display screen that is a built-in component of the computing device 800. The display device 810 can include a backlight (for example, any backlight illustrated or described herein). The display device 810 may also include a computer monitor, television, or projector, among others, that is externally connected to the computing device 800. The display device 810 can include liquid crystal display (LCD), light emitting diodes (LEDs), organic light emitting diodes (OLEDs), and/or micro-LEDs (μLEDs), among others. In some embodiments, display device 810 can be any display device described or illustrated herein. In some embodiments, display device 810 can include any portion of any display device or display backlight described or illustrated herein.

In some embodiments, the display interface 808 can include any suitable graphics processing unit, transmitter, port, physical interconnect, and the like. In some examples, the display interface 808 can implement any suitable protocol for transmitting data to the display device 810. For example, the display interface 808 can transmit data using a high-definition multimedia interface (HDMI) protocol, a DisplayPort protocol, or some other protocol or communication link, and the like

In some embodiments, display device 810 includes a display controller. In some embodiments, the display device 810 or the display controller can include a video processor as described or illustrated herein (for example, video processor 606). In some embodiments, the display controller can provide control signals within and/or to the display device 810. In some embodiments, the display controller can be included in the display interface 808 (and/or instead of the display interface 808). In some embodiments, the display controller can be coupled between the display interface 808 and the display device 810. In some embodiments, the display controller can be coupled between the display interface 808 and the interconnect 806. In some embodiments, the display controller can be included in the processor 802. In some embodiments, the display controller can implement control of a display and/or a backlight of display device 810 according to any example illustrated or described herein.

In some embodiments, any of the techniques described in this specification can be implemented entirely or partially within the display device 810. In some embodiments, any of the techniques described in this specification can be implemented entirely or partially within the display controller. In some embodiments, any of the techniques described in this specification can be implemented entirely or partially within the processor 802. In some embodiments, any of the techniques described in this specification can be implemented entirely or partially within a liquid crystal display (LCD) module (for example, which LCD module may be entirely or partially implemented within one or more of processor 802, display interface 808, display device 810, and/or the display controller).

In addition, a network interface controller (also referred to herein as a NIC) 812 may be adapted to connect the computing device 800 through the system interconnect 806 to a network (not depicted). The network (not depicted) may be a wireless network, a wired network, cellular network, a radio network, a wide area network (WAN), a local area network (LAN), a global position satellite (GPS) network, and/or the Internet, among others.

The processor 802 may be connected through system interconnect 806 to an input/output (I/O) device interface 814 adapted to connect the computing host device 800 to one or more I/O devices 816. The I/O devices 816 may include, for example, a keyboard and/or a pointing device, where the pointing device may include a touchpad or a touchscreen, among others. The I/O devices 816 may be built-in components of the computing device 800, or may be devices that are externally connected to the computing device 800.

In some embodiments, the processor 802 may also be linked through the system interconnect 806 to a storage device 818 that can include a hard drive, a solid state drive (SSD), a magnetic drive, an optical drive, a portable drive, a flash drive, a Universal Serial Bus (USB) flash drive, an array of drives, and/or any other type of storage, including combinations thereof. In some embodiments, the storage device 818 can include any suitable applications. In some embodiments, the storage device 818 can include image stick avoidance 820. In some embodiments, image stick avoidance 820 can include instructions that can be executed by a processor such as processor 802, a video processor, or a display controller, among others. In some embodiments, image stick avoidance 820 can include anything described or illustrated herein, such as that illustrated in and described in reference to FIG. 6 or FIG. 7.

It is to be understood that the block diagram of FIG. 8 is not intended to indicate that the computing device 800 is to include all of the components shown in FIG. 8. Rather, the computing device 800 can include fewer and/or additional components not illustrated in FIG. 8 (e.g., additional memory components, embedded controllers, additional modules, additional network interfaces, etc.). Furthermore, any of the functionalities of image stick avoidance 820 may be partially, or entirely, implemented in hardware and/or in the processor 802. For example, the functionality may be implemented with an application specific integrated circuit, logic implemented in an embedded controller, or in logic implemented in the processor 802, among others. In some embodiments, the functionalities of image stick avoidance 820 can be implemented with logic, wherein the logic, as referred to herein, can include any suitable hardware (e.g., a processor, among others), software (e.g., an application, among others), firmware, or any suitable combination of hardware, software, and firmware.

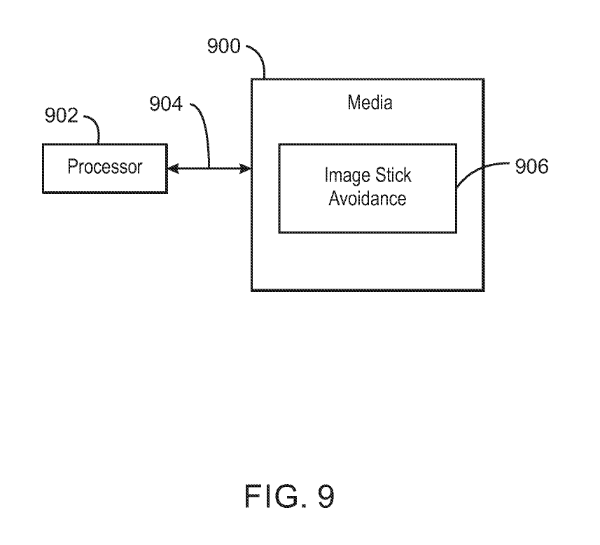

FIG. 9 is a block diagram of an example of one or more processor and one or more tangible, non-transitory computer readable media. The one or more tangible, non-transitory, computer-readable media 900 may be accessed by a processor 902 over a computer interconnect 904. Furthermore, the one or more tangible, non-transitory, computer-readable media 900 may include code to direct the processor 902 to perform operations as described herein. For example, in some embodiments, computer-readable media 900 may include code to direct the processor to perform image stick avoidance according to some embodiments. In some embodiments, processor 902 is one or more processors. In some embodiments, processor 902 can perform similarly to (and/or the same as) processor 802 of FIG. 8, and/or can perform some or all of the same functions as can be performed by processor 802.

Various components discussed in this specification may be implemented using software components. These software components may be stored on the one or more tangible, non-transitory, computer-readable media 900, as indicated in FIG. 9. For example, software able to perform image stick avoidance may be included in one or more computer readable media 900 according to some embodiments. Image stick avoidance 906 may be adapted to direct the processor 902 to perform one or more of any of the operations described in this specification and/or in reference to the drawings.

It is to be understood that any suitable number of software components may be included within the one or more tangible, non-transitory computer-readable media 900. Any number of additional software components not shown in FIG. 9 may be included within the one or more tangible, non-transitory, computer-readable media 900, depending on the specific application.

In some embodiments, any of the techniques described in this specification and/or illustrated in the drawings can be implemented in a liquid crystal display (LCD) module, a display, a display backlight, a display controller, a processor, or a video processor, among others. In some embodiments, any of the techniques described in this specification and/or illustrated in the drawings can be implemented in a display backlight driver. In some embodiments, any of the techniques described in this specification and/or illustrated in the drawings can be implemented in a mobile and/or portable computing device (for example, in an LCD module of a mobile and/or portable computing device).

Reference in the specification to “one embodiment” or “an embodiment” or “some embodiments” of the disclosed subject matter means that a particular feature, structure, or characteristic described in connection with the embodiment is included in at least one embodiment of the disclosed subject matter. Thus, the phrase “in one embodiment” or “in some embodiments” may appear in various places throughout the specification, but the phrase may not necessarily refer to the same embodiment or embodiments.

### EXAMPLE 1

In some examples, a display backlight includes white organic light emitting diodes patterned in a segmented manner, and one or more spacers spaced between the white organic light emitting diodes.

### EXAMPLE 2

In some examples, a display backlight includes white organic light emitting diodes patterned in a segmented manner, one or more spacers spaced between the white organic light emitting diodes, and a substrate adjacent to the white organic light emitting diodes and the one or more spacers.

### EXAMPLE 3

In some examples, a display backlight includes white organic light emitting diodes patterned in a segmented manner, one or more spacers spaced between the white organic light emitting diodes, and an encapsulation layer to encapsulate the white organic light emitting diodes.

### EXAMPLE 4

In some examples, a display backlight includes white organic light emitting diodes patterned in a segmented manner, one or more spacers spaced between the white organic light emitting diodes, a substrate adjacent to the white organic light emitting diodes and the one or more spacers, and encapsulation layer to encapsulate the white organic light emitting diodes.

### EXAMPLE 5

In some examples, a display backlight includes white organic light emitting diodes patterned in a segmented manner, and one or more spacers spaced between the white organic light emitting diodes, wherein the white organic light emitting diodes are patterned in an array of rows and columns separated by the one or more spacers.

### EXAMPLE 6

In some examples, a display includes a display screen and a backlight. The backlight includes white organic light emitting diodes patterned in a segmented manner, and one or more spacers spaced between the white organic light emitting diodes.

### EXAMPLE 7

In some examples, a display includes a display screen and a backlight. The backlight includes white organic light emitting diodes patterned in a segmented manner, one or more spacers spaced between the white organic light emitting diodes, and a substrate, the white organic light emitting diodes and the one or more spacers formed on a layer above the substrate.

### EXAMPLE 8

In some examples, a display includes a display screen and a backlight. The backlight includes white organic light emitting diodes patterned in a segmented manner, one or more spacers spaced between the white organic light emitting diodes, and an encapsulation layer to encapsulate the white organic light emitting diodes.

### EXAMPLE 9

In some examples, a display includes a display screen and a backlight. The backlight includes white organic light emitting diodes patterned in a segmented manner, one or more spacers spaced between the white organic light emitting diodes, a substrate, the white organic light emitting diodes and the one or more spacers formed on a layer above the substrate, and an encapsulation layer to encapsulate the white organic light emitting diodes.

### EXAMPLE 10

In some examples, a display includes a display screen and a backlight. The backlight includes white organic light emitting diodes patterned in a segmented manner, and one or more spacers spaced between the white organic light emitting diodes. The white organic light emitting diodes are patterned in an array of rows and columns separated by the one or more spacers.

### EXAMPLE 11

In some examples, a display includes a display screen and a backlight. The backlight includes white organic light emitting diodes patterned in a segmented manner, and one or more spacers spaced between the white organic light emitting diodes. The display screen is a liquid crystal display screen.

### EXAMPLE 12

In some examples, a method of forming a display includes forming a display screen, forming a substrate, forming on the substrate a pattern of white organic light emitting diodes, and encapsulating the white organic light emitting diodes.

### EXAMPLE 13

In some examples, a method of forming a display includes forming a display screen, forming a substrate, forming on the substrate a pattern of white organic light emitting diodes, and encapsulating the white organic light emitting diodes, and assembling the display screen together with the substrate and the encapsulated white organic light emitting diodes.

### EXAMPLE 14

In some examples, a method of forming a display includes forming a display screen, forming a substrate, forming on the substrate a pattern of white organic light emitting diodes, and encapsulating the white organic light emitting diodes. The white organic light emitting diodes are patterned in an array of rows and columns separated by one or more one or more spacers.

### EXAMPLE 15

In some examples, a method of forming a display includes forming a display screen, forming a substrate, forming on the substrate a pattern of white organic light emitting diodes, and encapsulating the white organic light emitting diodes. The display screen is a liquid crystal display (LCD) screen.

### EXAMPLE 16

In some examples, a system includes storage to store instructions, and a processor to execute the instructions to monitor a display image and determine if the display image is static. If the display image is static, the processor to execute the instructions to turn on pixels in a display backlight (for example, to turn on all pixels in a display backlight).

### EXAMPLE 17

In some examples, a system includes storage to store instructions, and a processor to execute the instructions to monitor a display image and determine if the display image is static. If the display image is static, the processor to execute the instructions to turn on pixels in a display backlight (for example, to turn on all pixels in a display backlight). The processor is also to execute the instructions to drive the display backlight in a high dynamic range mode if the display image is not static.

### EXAMPLE 18

In some examples, a system includes storage to store instructions, and a processor to execute the instructions to monitor a display image and determine if the display image is static. If the display image is static, the processor to execute the instructions to turn on pixels in a display backlight (for example, to turn on all pixels in a display backlight). The processor is also to monitor a video frame buffer (for example, to monitor the display image).

### EXAMPLE 19

In some examples, a system includes storage to store instructions, and a processor to execute the instructions to monitor a display image and determine if the display image is static. If the display image is static, the processor to execute the instructions to turn on pixels in a display backlight (for example, to turn on all pixels in a display backlight). The display backlight includes white organic light emitting diodes patterned in a segmented manner and one or more spacers spaced between the white organic light emitting diodes.

### EXAMPLE 20

In some examples, a system includes storage to store instructions, and a processor to execute the instructions to monitor a display image and determine if the display image is static. If the display image is static, the processor to execute the instructions to turn on pixels in a display backlight (for example, to turn on all pixels in a display backlight). The display backlight includes white organic light emitting diodes patterned in a segmented manner and one or more spacers spaced between the white organic light emitting diodes. The display backlight also includes a substrate adjacent to the white organic light emitting diodes and the one or more spacers.

### EXAMPLE 21

In some examples, a system includes storage to store instructions, and a processor to execute the instructions to monitor a display image and determine if the display image is static. If the display image is static, the processor to execute the instructions to turn on pixels in a display backlight (for example, to turn on all pixels in a display backlight). The display backlight includes white organic light emitting diodes patterned in a segmented manner and one or more spacers spaced between the white organic light emitting diodes. The display backlight also includes an encapsulation layer to encapsulate the white organic light emitting diodes.

### EXAMPLE 22

In some examples, a system includes storage to store instructions, and a processor to execute the instructions to monitor a display image and determine if the display image is static. If the display image is static, the processor to execute the instructions to turn on pixels in a display backlight (for example, to turn on all pixels in a display backlight). The display backlight includes white organic light emitting diodes patterned in a segmented manner and one or more spacers spaced between the white organic light emitting diodes. The white organic light emitting diodes are patterned in an array of rows and columns separated by the one or more spacers.

### EXAMPLE 23

In some examples, one or more tangible, non-transitory machine readable media include a plurality of instructions that, in response to being executed on at least one processor, cause the at least one processor to monitor a display image and determine if the display image is static. If the display image is static, the instructions cause the at least one processor to turn on pixels in a display backlight (for example, to turn on all pixels in a backlight display).

### EXAMPLE 24

In some examples, one or more tangible, non-transitory machine readable media include a plurality of instructions that, in response to being executed on at least one processor, cause the at least one processor to monitor a display image and determine if the display image is static. If the display image is static, the instructions cause the at least one processor to turn on pixels in a display backlight (for example, to turn on all pixels in a backlight display). The instructions also cause the at least one processor to drive the display backlight in a high dynamic range mode if the display image is not static.

### EXAMPLE 25

In some examples, one or more tangible, non-transitory machine readable media include a plurality of instructions that, in response to being executed on at least one processor, cause the at least one processor to monitor a display image and determine if the display image is static. If the display image is static, the instructions cause the at least one processor to turn on pixels in a display backlight (for example, to turn on all pixels in a backlight display). The instructions also cause the at least one processor to monitor a video frame buffer (for example, to monitor the display image).

### EXAMPLE 26

In some examples, one or more tangible, non-transitory machine readable media include a plurality of instructions that, in response to being executed on at least one processor, cause the at least one processor to monitor a display image and determine if the display image is static. If the display image is static, the instructions cause the at least one processor to turn on pixels in a display backlight (for example, to turn on all pixels in a backlight display). The display backlight includes white organic light emitting diodes patterned in a segmented manner and one or more spacers spaced between the white organic light emitting diodes.

### EXAMPLE 27

In some examples, a display backlight includes white organic light emitting diodes patterned in a segmented manner and one or more spacers spaced between the white organic light emitting diodes. A substrate can be adjacent to the white organic light emitting diodes and the one or more spacers. An encapsulation layer can encapsulate the white organic light emitting diodes. The white organic light emitting diodes can be patterned in an array of rows and columns separated by the one or more spacers. A display can include a display screen and the display backlight. The display screen can be a liquid crystal display screen.

### EXAMPLE 28

In some examples, a method of forming a display includes forming a display screen, forming a substrate, forming on the substrate a pattern of white organic light emitting diodes, and encapsulating the white organic light emitting diodes. The display screen can be assembled together with the substrate and the encapsulated white organic light emitting diodes. The white organic light emitting diodes can be patterned in an array of rows and columns separated by one or more spacers. The display screen can be a liquid crystal display screen.

### EXAMPLE 29

In some examples, a system includes storage to store instructions, and a processor to execute the instructions to monitor a display image, determine if the display image is static, and if the display image is static, turn on pixels in a display backlight. The processor can execute the instructions to drive the display backlight in a high dynamic range mode if the display image is not static. The processor can execute the instructions to monitor a video frame buffer. The display backlight can include white organic light emitting diodes patterned in a segmented manner and one or more spacers spaced between the white organic light emitting diodes. The display backlight can include a substrate adjacent to the white organic light emitting diodes and the one or more spacers. The display backlight can include an encapsulation layer to encapsulate the white organic light emitting diodes. The white organic light emitting diodes can be patterned in an array of rows and columns separated by the one or more spacers.

### EXAMPLE 30

In some examples, a system includes means for monitoring a display image, means for determining if the display image is static, and means for turning on pixels in a display backlight if the display image is static. The system can include means for driving the display backlight in a high dynamic range mode if the display image is not static. The system can include means for monitoring a video frame buffer. The display backlight can include white organic light emitting diodes patterned in a segmented manner and one or more spacers spaced between the white organic light emitting diodes. The display backlight can include a substrate adjacent to the white organic light emitting diodes and the one or more spacers. The display backlight can include an encapsulation layer to encapsulate the white organic light emitting diodes. The white organic light emitting diodes can be patterned in an array of rows and columns separated by the one or more spacers.

### EXAMPLE 31

In some examples, one or more tangible, non-transitory machine readable media include a plurality of instructions that, in response to being executed on at least one processor, cause the at least one processor to monitor a display image, determine if the display image is static, and if the display image is static, turn on pixels in a display backlight. The one or more tangible, non-transitory machine readable media can include a plurality of instructions that, in response to being executed on the at least one processor, cause the at least one processor to drive the display backlight in a high dynamic range mode if the display image is not static. The one or more tangible, non-transitory machine readable media can include a plurality of instructions that, in response to being executed on at least one processor, cause the at least one processor to monitor a video frame buffer. The display backlight can include white organic light emitting diodes patterned in a segmented manner and one or more spacers spaced between the white organic light emitting diodes.

### EXAMPLE 32

In some examples, a method includes monitoring a display image, determining if the display image is static, and if the display image is static, turning on pixels in a display backlight. The method can include driving the display backlight in a high dynamic range mode if the display image is not static. The method can include monitoring a video frame buffer. The display backlight can include white organic light emitting diodes patterned in a segmented manner and one or more spacers spaced between the white organic light emitting diodes. The display backlight can include a substrate adjacent to the white organic light emitting diodes and the one or more spacers. The display backlight can include an encapsulation layer to encapsulate the white organic light emitting diodes. The white organic light emitting diodes can be patterned in an array of rows and columns separated by the one or more spacers.

### EXAMPLE 33

In some examples, a display apparatus includes white organic light emitting diodes patterned in a segmented manner, and one or more spacers spaced between the white organic light emitting diodes.

### EXAMPLE 34

In any preceding example, a substrate can be adjacent to the white organic light emitting diodes and the one or more spacers.

### EXAMPLE 35

In any preceding example, an encapsulation layer can encapsulate the white organic light emitting diodes.

### EXAMPLE 36

In any preceding example, the white organic light emitting diodes can be patterned in an array of rows and columns separated by the one or more spacers.

### EXAMPLE 37

In any preceding example, a display screen can be included.

### EXAMPLE 38

In any preceding example, the display screen can be a liquid crystal display screen.

### EXAMPLE 39

In any preceding example, the display can be a liquid crystal display.

### EXAMPLE 40

In any preceding example, the display screen can be a liquid crystal display screen.

### EXAMPLE 41

In any preceding example, the display or display screen can include a substrate, the white organic light emitting diodes and the one or more spacers formed on a layer above the substrate.

### EXAMPLE 42

In any preceding example, a display or an apparatus can include means for monitoring a display image, means for determining if the display image is static, and means for turning on pixels in a backlight of the display apparatus if the display image is static. The display or apparatus can include means for driving the display backlight in a high dynamic range mode if the display image is not static.

### EXAMPLE 43

In any preceding example, a display or an apparatus can include means for monitoring a video frame buffer.

### EXAMPLE 44

A method of forming a display, display backlight, or apparatus of any preceding example. The method can include forming a display screen, forming a substrate, forming on the substrate a pattern of white organic light emitting diodes, and encapsulating the white organic light emitting diodes.

### EXAMPLE 45

A method of forming a display, display backlight, or apparatus of any preceding example, including assembling the display screen together with the substrate and the encapsulated white organic light emitting diodes.

### EXAMPLE 46

Machine-readable storage including machine-readable instructions, when executed, to implement a method or realize an apparatus as in any preceding example.

Although example embodiments of the disclosed subject matter are described with reference to the figures, persons of ordinary skill in the art will readily appreciate that many other ways of implementing the disclosed subject matter may alternatively be used. For example, the order of execution of the blocks in flow diagrams may be changed, and/or some of the blocks in block/flow diagrams described may be changed, eliminated, or combined. Additionally, some of the circuit and/or block elements may be changed, eliminated, or combined.

In the preceding description, various aspects of the disclosed subject matter have been described. For purposes of explanation, specific numbers, systems and configurations were set forth in order to provide a thorough understanding of the subject matter. However, it is apparent to one skilled in the art having the benefit of this disclosure that the subject matter may be practiced without the specific details. In other instances, well-known features, components, or modules were omitted, simplified, combined, or split in order not to obscure the disclosed subject matter.

Various embodiments of the disclosed subject matter may be implemented in hardware, firmware, software, or combination thereof, and may be described by reference to or in conjunction with program code, such as instructions, functions, procedures, data structures, logic, application programs, design representations or formats for simulation, emulation, and fabrication of a design, which when accessed by a machine results in the machine performing tasks, defining abstract data types or low-level hardware contexts, or producing a result.

Program code may represent hardware using a hardware description language or another functional description language which essentially provides a model of how designed hardware is expected to perform. Program code may be assembly or machine language or hardware-definition languages, or data that may be compiled and/or interpreted. Furthermore, it is common in the art to speak of software, in one form or another as taking an action or causing a result. Such expressions are merely a shorthand way of stating execution of program code by a processing system which causes a processor to perform an action or produce a result.

Program code may be stored in, for example, volatile and/or non-volatile memory, such as storage devices and/or an associated machine readable or machine accessible medium including solid-state memory, hard-drives, floppy-disks, optical storage, tapes, flash memory, memory sticks, digital video disks, digital versatile discs (DVDs), etc., as well as more exotic mediums such as machine-accessible biological state preserving storage. A machine readable medium may include any tangible mechanism for storing, transmitting, or receiving information in a form readable by a machine, such as antennas, optical fibers, communication interfaces, etc. Program code may be transmitted in the form of packets, serial data, parallel data, etc., and may be used in a compressed or encrypted format.

Program code may be implemented in programs executing on programmable machines such as mobile or stationary computers, personal digital assistants, set top boxes, cellular telephones and pagers, and other electronic devices, each including a processor, volatile and/or non-volatile memory readable by the processor, at least one input device and/or one or more output devices. Program code may be applied to the data entered using the input device to perform the described embodiments and to generate output information. The output information may be applied to one or more output devices. One of ordinary skill in the art may appreciate that embodiments of the disclosed subject matter can be practiced with various computer system configurations, including multiprocessor or multiple-core processor systems, minicomputers, mainframe computers, as well as pervasive or miniature computers or processors that may be embedded into virtually any device. Embodiments of the disclosed subject matter can also be practiced in distributed computing environments where tasks may be performed by remote processing devices that are linked through a communications network.

Although operations may be described as a sequential process, some of the operations may in fact be performed in parallel, concurrently, and/or in a distributed environment, and with program code stored locally and/or remotely for access by single or multi-processor machines. In addition, in some embodiments the order of operations may be rearranged without departing from the spirit of the disclosed subject matter. Program code may be used by or in conjunction with embedded controllers.

While the disclosed subject matter has been described with reference to illustrative embodiments, this description is not intended to be construed in a limiting sense. Various modifications of the illustrative embodiments, as well as other embodiments of the subject matter, which are apparent to persons skilled in the art to which the disclosed subject matter pertains are deemed to lie within the scope of the disclosed subject matter. For example, in each illustrated embodiment and each described embodiment, it is to be understood that the diagrams of the figures and the description herein is not intended to indicate that the illustrated or described devices include all of the components shown in a particular figure or described in reference to a particular figure. In addition, each element may be implemented with logic, wherein the logic, as referred to herein, can include any suitable hardware (e.g., a processor, among others), software (e.g., an application, among others), firmware, or any suitable combination of hardware, software, and firmware, for example.

What is claimed is:

1. A display backlight comprising:
white organic light emitting diodes patterned in a segmented manner; and
one or more spacers spaced between the white organic light emitting diodes.

2. The display backlight of claim 1, comprising a substrate adjacent to the white organic light emitting diodes and the one or more spacers.

3. The display backlight of claim 1, comprising an encapsulation layer to encapsulate the white organic light emitting diodes.

4. The display backlight of claim 2, comprising an encapsulation layer to encapsulate the white organic light emitting diodes.

5. The display backlight of claim 1, wherein the white organic light emitting diodes are patterned in an array of rows and columns separated by the one or more spacers.

6. A display comprising:
a display screen; and
a backlight including white organic light emitting diodes patterned in a segmented manner, and one or more spacers spaced between the white organic light emitting diodes.

7. The display of claim 6, the display backlight comprising a substrate, the white organic light emitting diodes and the one or more spacers formed on a layer above the substrate.

8. The display of claim 6, the display backlight comprising an encapsulation layer to encapsulate the white organic light emitting diodes.

9. The display of claim 7, the display backlight comprising an encapsulation layer to encapsulate the white organic light emitting diodes.

10. The display of claim 6, wherein the white organic light emitting diodes are patterned in an array of rows and columns separated by the one or more spacers.

11. The display of claim 6, wherein the display screen is a liquid crystal display screen.

12. A method of forming a display, comprising:
forming a display screen;
forming a substrate;
forming on the substrate a pattern of white organic light emitting diodes; and
encapsulating the white organic light emitting diodes.

13. The method of forming a display of claim 12, comprising assembling the display screen together with the substrate and the encapsulated white organic light emitting diodes.

14. The method of claim 12, wherein the white organic light emitting diodes are patterned in an array of rows and columns separated by one or more spacers.

15. The method of claim 12, wherein the display screen is a liquid crystal display screen.

16. A system comprising:
storage to store instructions; and
a processor to execute the instructions to:
monitor a display image;
determine if the display image is static; and
if the display image is static, turn on pixels in a display backlight.

17. The system of claim 16, the processor to execute the instructions to drive the display backlight in a high dynamic range mode if the display image is not static.

18. The system of claim 16, the processor to execute the instructions to monitor a video frame buffer.

19. The system of claim 16, wherein the display backlight includes white organic light emitting diodes patterned in a segmented manner and one or more spacers spaced between the white organic light emitting diodes.

20. The system of claim 19, wherein the display backlight includes a substrate adjacent to the white organic light emitting diodes and the one or more spacers.

21. The system of claim 19, wherein the display backlight includes an encapsulation layer to encapsulate the white organic light emitting diodes.

22. The system of claim 19, wherein the white organic light emitting diodes are patterned in an array of rows and columns separated by the one or more spacers.

23. One or more tangible, non-transitory machine readable media comprising a plurality of instructions that, in response to being executed on at least one processor, cause the at least one processor to:
monitor a display image;
determine if the display image is static; and
if the display image is static, turn on pixels in a display backlight.

24. The one or more tangible, non-transitory machine readable media of claim 24, comprising a plurality of instructions that, in response to being executed on the at least one processor, cause the at least one processor to:
drive the display backlight in a high dynamic range mode if the display image is not static.

25. The one or more tangible, non-transitory machine readable media of claim 24, comprising a plurality of instructions that, in response to being executed on at least one processor, cause the at least one processor to:
monitor a video frame buffer.

26. The one or more tangible, non-transitory machine readable media of claim 24, wherein the display backlight includes white organic light emitting diodes patterned in a segmented manner and one or more spacers spaced between the white organic light emitting diodes.
